(19) United States
(12) Patent Application Publication
(10) Pub. No.: US 2022/0109431 A1
(43) Pub. Date: Apr. 7, 2022

(54) PHASE SHIFTER AND METHOD OF MANUFACTURING PHASE SHIFTER

(71) Applicant: Mitsubishi Electric Corporation, Tokyo (JP)

(72) Inventor: Yoshihiro TSUKAHARA, Tokyo (JP)

(73) Assignee: Mitsubishi Electric Corporation, Tokyo (JP)

(21) Appl. No.: 17/419,132

(22) PCT Filed: Mar. 18, 2019
(86) PCT No.: PCT/JP2019/011074

§ 371 Date: Jun. 28, 2021

(51) Int. Cl. H03H 11/16; H03H 3/00

(52) U.S. Cl. CPC H03H 11/16; H03H 3/00

(57) ABSTRACT

A phase shifter includes: a first transistor including a first source and a first drain; a second transistor including a second source and a second drain; a first inductor connected with the first source and the first drain, connected in parallel with the first transistor, and including a first body part having an interrupted part, and a first connection part formed at the interrupted part; a second inductor connected with the second source and the second drain, connected in parallel with the second transistor, and including a second body part having an interrupted part, and a second connection part formed at the interrupted part; an inspection drain terminal connected with the first drain and the second drain; and an inspection source terminal connected with the first source and the second source.

### FIELD

The present invention relates to a phase shifter and a method of manufacturing the phase shifter.

### BACKGROUND

In a phase shifter circuit used in, for example, a radar instrument of a high frequency band or a millimeter wave band, an inductor is connected in parallel with a FET in some cases. Phase switching in the phase shifter circuit is performed through switching operation of the FET by applying ON voltage (Vg=0 V)/OFF voltage (Vg<FET pinch-off voltage Vp) to the gate of the FET, and thus the DC characteristic (Vp characteristic) of the FET is important. Patent Literature 1 discloses, as a method of performing DC inspection (Vp inspection) of a FET connected in parallel with an inductor, a structure in which FETs are formed on a first surface of a semiconductor substrate, an inspection terminal of each FET is provided, and inspection pads corresponding to the respective FETs are provided on a second surface through a through-hole.

### CITATION LIST

### Patent Literature

### [Patent Literature 1] JP 2008-10640 A

### SUMMARY

### Technical Problem

Patent Literature 1 is a structure in which an inspection terminal is connected with the semiconductor substrate through a through-hole, which leads to increase of the number of through-holes and potentially degrades the strength of a semiconductor device.

The present invention is intended to solve the above-described problem and provide a high-quality phase shifter that can perform Vp inspection of a FET in a semiconductor manufacturing process and can simplify an inspection process by sharing an inspection terminal to simultaneously perform Vp inspection of a plurality of FETs, and a method of manufacturing the phase shifter.

### Solution to Problem

A phase shifter according to the present disclosure includes: a first transistor including a first source and a first drain; a second transistor including a second source and a second drain; a first inductor connected with the first source and the first drain, connected in parallel with the first transistor, and including a first body part having an interrupted part, and a first connection part formed at the interrupted part; a second inductor connected with the second source and the second drain, connected in parallel with the second transistor, and including a second body part having an interrupted part, and a second connection part formed at the interrupted part; an inspection drain terminal connected with the first drain and the second drain; and an inspection source terminal connected with the first source and the second source.

A method of manufacturing a phase shifter according to the present disclosure includes: forming a first body part connected with a first source and a first drain of a first transistor and having an interrupted part; forming a second body part connected with a second source and a second drain of a second transistor and having an interrupted part; inspecting DC characteristics of the first transistor and the second transistor by using an inspection drain terminal connected with the first drain and the second drain, and an inspection source terminal connected with the first source and the second source; forming a first connection part at the interrupted part of the first body part and forming a first inductor or a first microstrip line including the first body part and the first connection part; and forming a second connection part at the interrupted part of the second body part and forming a second inductor or a second microstrip line including the second body part and the second connection part.

Other features of the present disclosure will be clarified below.

### Advantageous Effects of Invention

In the present disclosure, inductors etc. are formed through two separate processes, and an inspection terminal is shared. Therefore, the inspection process can be simplified.

### BRIEF DESCRIPTION OF THE DRAWINGS

FIG. 1 is a circuit diagram of a phase shifter according to Embodiment 1.

FIG. 2 is a diagram illustrating the uncompleted first inductor.

FIG. 3 is a diagram illustrating the completed first inductor.

FIG. 4 is a diagram illustrating the uncompleted second inductor.

FIG. 5 is a diagram illustrating the completed second inductors.

FIG. 6 is a circuit diagram of a phase shifter according to Embodiment 2.

FIG. 7 is a diagram illustrating the uncompleted first microstrip line.

FIG. 8 is a diagram illustrating the completed first microstrip line.

FIG. 9 is a diagram illustrating the uncompleted second microstrip lines.

FIG. 10 is a diagram illustrating the completed second microstrip lines.

FIG. 11 is a circuit diagram of a phase shifter according to Embodiment 3.

### DESCRIPTION OF EMBODIMENTS

A phase shifter and a method of manufacturing the phase shifter according to the embodiments of the present disclosure will be described with reference to the drawings. The same components will be denoted by the same symbols, and the repeated description thereof may be omitted.

### Embodiment 1

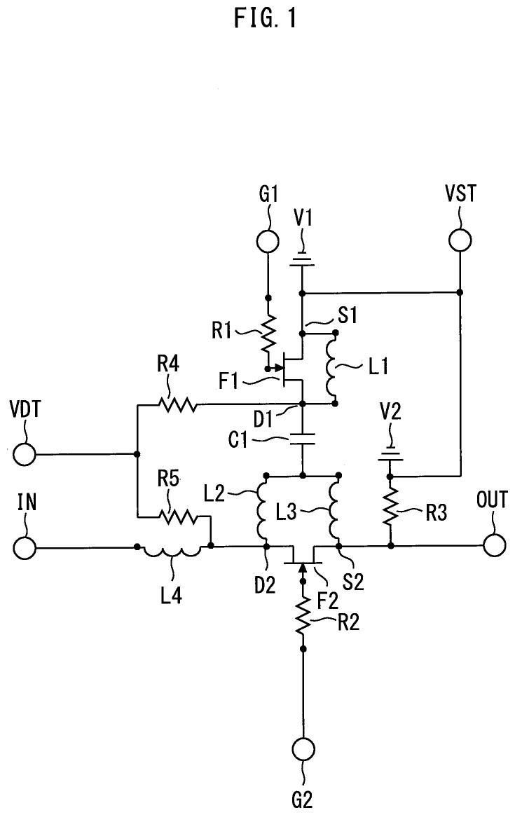

FIG. 1 is a circuit diagram of a phase shifter formed on a semiconductor substrate according to Embodiment 1. This phase shifter is a phase shifter including a field effect transistor (FET) and used in a high frequency band. The phase shifter includes a first transistor F1 including a first source S1 and a first drain D1, and a second transistor F2 including a second source S2 and a second drain D2. The first transistor F1 and the second transistor F2 are field effect transistors.

A control terminal G1 is connected with the gate of the first transistor F1 through a resistor R1. A control terminal G2 is connected with the gate of the second transistor F2 through a resistor R2. A first inductor L1 is connected with the first source S1 and the first drain D1. Second inductors L2 and L3 are connected with the second source S2 and the second drain D2. The second inductor L2 is connected with the second drain D2, the second inductor L3 is connected with the second source S2, and the second inductor L2 and the second inductor L3 are connected with each other.

A matching inductor L4 is provided on a wire connecting an input terminal IN and the second drain D2. A matching capacitor C1 is provided on a wire connecting an intermediate point between the second inductors L2 and L3 and the first drain D1. An inspection drain terminal VDT is connected with the first drain D1 through a first resistor R4. The first resistor R4 is a resistor connected in series with a wire connecting the first drain D1 and the inspection drain terminal VDT. The resistance value of the first resistor R4 is, for example, 2 kΩ or higher.

The inspection drain terminal VDT is connected with the second drain D2 through a second resistor R5. The second resistor R5 is a resistor connected in series with a wire connecting the second drain D2 and the inspection drain terminal VDT. The resistance value of the second resistor R5 is, for example, 2 kΩ or higher. The inspection drain terminal VDT is a common terminal connected with the first drain D1 and the second drain D2.

An inspection source terminal VST that functions as a common terminal is connected with the first source S1 and the second source S2. The first source S1 is directly connected with the inspection source terminal VST, and the second source S2 is connected with the inspection source terminal VST through a resistor R3.

These elements included in a circuit may be mainly formed on a first surface of a semiconductor substrate. The first inductor L1, the second inductors L2 and L3, and the inductor L4 may be each a spiral inductor having a two-layer wiring structure. The two-layer wiring structure means that the entire structure is constituted by parts formed through two separate processes. Ground terminals V1 and V2 are each grounded through a via hole formed in the semiconductor substrate. The resistance values of the resistor R3, the first resistor R4, and the second resistor R5 may be high enough not to affect a typical high frequency band signal. For example, the resistance values of the resistor R3, the first resistor R4, and the second resistor R5 may be 2 kΩ or higher.

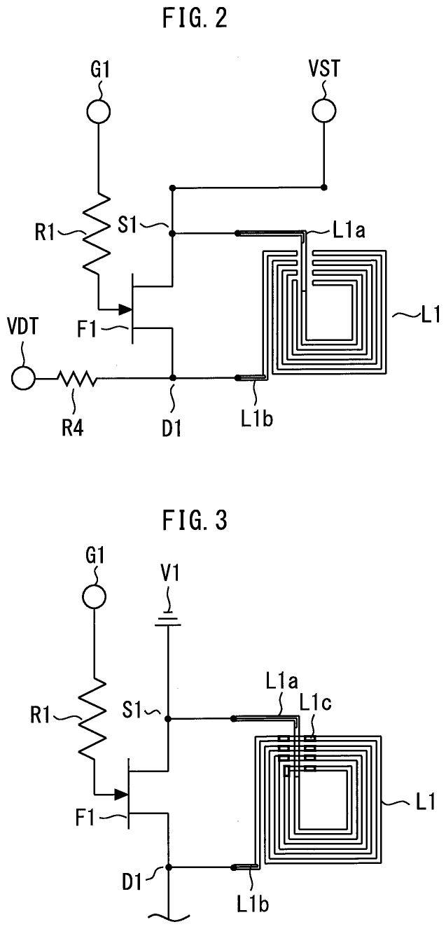

The following describes a method of manufacturing the above-described phase shifter. First, part of the first inductor L1 and part of the second inductors L2 and L3 are formed. FIG. 2 is a diagram illustrating the first inductor L1 that is partially formed and uncompleted. FIG. 2 omits part of the phase shifter to illustrate the first inductor in an enlarged manner. First body parts L1a and L1b including interrupted parts are formed as part of the first inductor. The first body part L1a is connected with the first source S1, and the first body part L1b is connected with the first drain D1. The first body part L1a and the first body part L1b are not connected with each other.

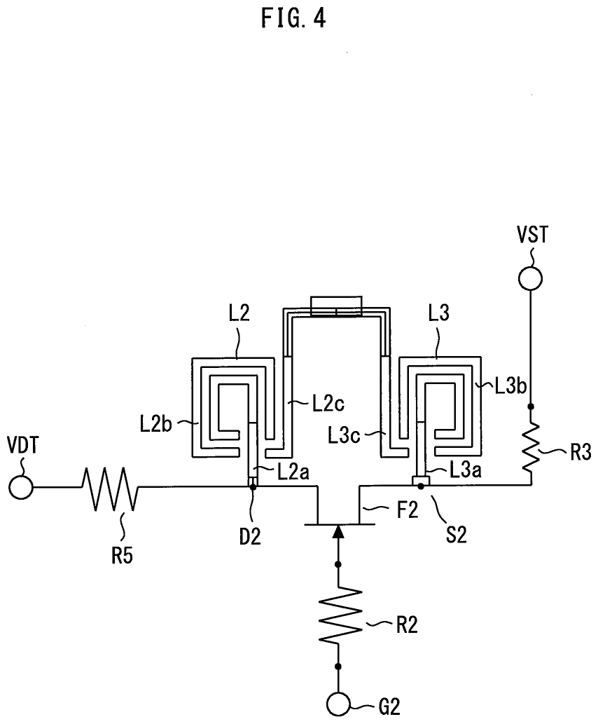

Part of the second inductors L2 and L3 is formed simultaneously with, before, or after the formation of the first body parts L1a and L1b. FIG. 4 is a diagram illustrating the second inductors L2 and L3 that are partially formed and uncompleted. Second body parts L2a, L2b, and L2c including interrupted parts are formed as part of the second inductor L2, and second body parts L3a, L3b, and L3c including interrupted parts are formed as part of the second inductor L3. The second body part L2a is connected with the second drain D2, and the second body part L3a is connected with the second source S2. However, each second body part is not in contact with any other second body part.

At this stage, no inductor is connected between the first source S1 and the first drain D1 of the first transistor F1 as illustrated in FIG. 2, and no inductor is connected between the second source S2 and the second drain D2 of the second transistor F2 as illustrated in FIG. 4.

Then, the DC characteristics of the first transistor F1 and the second transistor F2 are inspected by using the inspection drain terminal VDT connected with the first drain D1 and the second drain D2, and the inspection source terminal VST connected with the first source S1 and the second source S2. For example, the DC characteristics of the first transistor F1 and the second transistor F2 are inspected by applying 3 V as drain voltage to the inspection drain terminal VDT and applying 0 V to the inspection source terminal VST. In this case, the DC characteristic inspection is possible since no inductors are connected with the first transistor F1 and the second transistor F2. In the DC characteristic inspection, for example, the Vds-Id characteristics of the first transistor F1 and the second transistor F2 are measured. The Vds-Id characteristic measurement is an example of the Vp inspection.

Then, the first inductor L1 and the second inductors L2 and L3 are completed. FIG. 3 is a diagram illustrating the completed first inductor L1. As illustrated in FIG. 3, a first connection part L1c is formed at each interrupted part of the first body parts L1a and L1b, thereby forming the first inductor L1 including the first body parts L1a and L1b and the first connection parts L1c. Each bold rectangular part represents a first connection part L1c formed on the first body parts, and each part between two bold rectangles represents a first connection part L1c formed at the interrupted part of the first body parts. When the first connection part L1c is formed, the first source S1 and the first drain D1 are connected with each other through the first inductor L1. In other words, the first inductor L1 is connected in parallel with the first transistor F1.

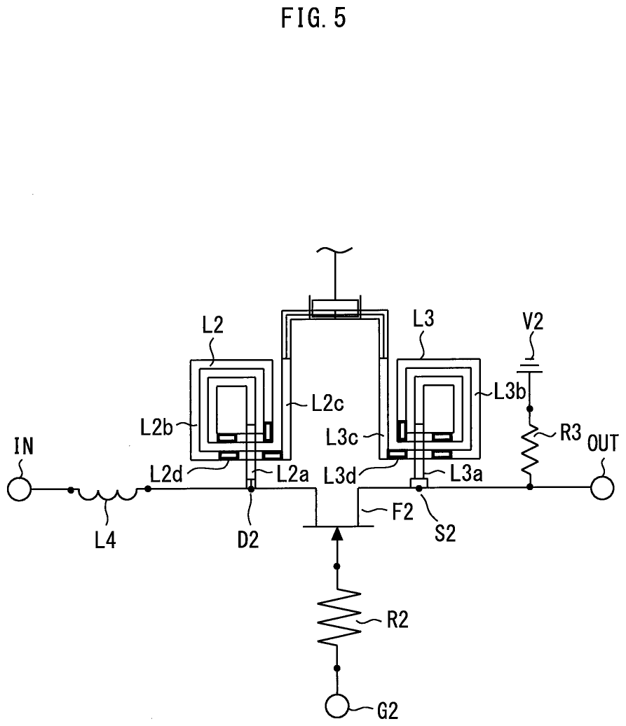

FIG. 5 is a diagram illustrating the completed second inductors L2 and L3. As illustrated in FIG. 5, second connection parts L2d are formed on the second body parts L2a, L2b, and L2c and at the interrupted parts thereof, thereby forming the second inductor L2 including the second body parts L2a, L2b, and L2c and the second connection parts L2d. In addition, second connection parts L3d are formed on the second body parts L3a, L3b, and L3c and at the interrupted parts thereof, thereby forming the second inductor L3 including the second body parts L3a, L3b, and L3c and the second connection parts L3d. Meaning of each bold rectangular is as described above. When the second connection parts L2d and the second connection parts L3d are formed, the second source S2 and the second drain D2 are connected with each other through the second inductors L2 and L3. In other words, the second inductors L2 and L3 are connected in parallel with the second transistor F2.

In a state in which each uncompleted inductor only including a body part is formed in this manner, the DC characteristics of the transistors are inspected, and connection parts of the inductors are formed after the inspection, which completes the inductors. For example, the first connection parts L1c and the second connection parts L2d and L3d may be formed by a plating method.

According to the above-described method of manufacturing the phase shifter, it is possible to simultaneously perform characteristic inspection on the first transistor F1 and the second transistor F2, without increasing the size of the phase shifter, by using the inspection source terminal VST and the inspection drain terminal VDT, which are shared between the two transistors. This can lead to a shortened inspection time. Although the present embodiment exemplarily describes a phase shifter including two transistors, simultaneous inspection can also be performed on a phase shifter including three or more transistors by sharing an inspection terminal.

Various modifications described in Embodiment 1 are also applicable to a phase shifter and a method of manufacturing the phase shifter according to embodiments below. In the phase shifter and the method of manufacturing the phase shifter according to the embodiments below, a large number of parts are common to those of Embodiment 1, and thus description will be mainly made on difference from Embodiment 1.

### Embodiment 2

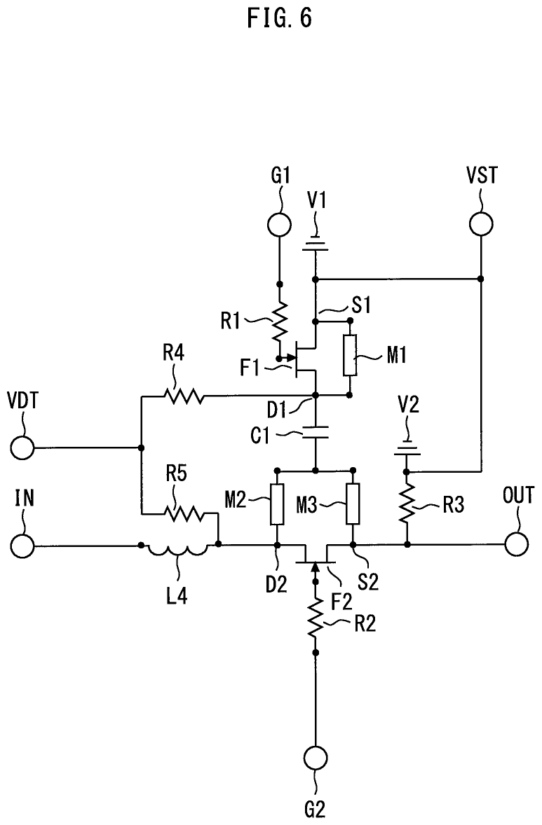

FIG. 6 is a circuit diagram of a phase shifter according to Embodiment 2. The phase shifter in FIG. 6 mainly operates in a millimeter wave band. In a case of a millimeter wave band circuit, a microstrip line is provided between the drain and the source of a transistor. Specifically, a first microstrip line M1 is connected with the first source and the first drain, a second microstrip line M2 is connected with the second drain D2, a second microstrip line M3 is connected with the second source S2, and the second microstrip line M2 and the second microstrip line M3 are connected with each other.

Since the phase shifter in FIG. 6 is mainly used in a millimeter wave band, the resistance value of the first resistor R4 connected in series with the wire connecting the first drain D1 and the inspection drain terminal VDT is 1.5 kΩ or higher, the resistance value of the second resistor R5 connected in series with the wire connecting the second drain D2 and the inspection drain terminal VDT is 1.5 kΩ or higher, and the resistance value of the resistor R3 is 1.5 kΩ or higher. The other circuit configurations are same as those in FIG. 1.

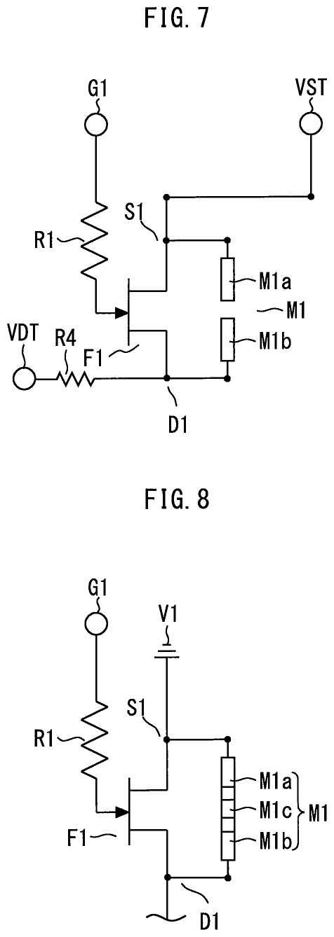

The following describes a method of manufacturing the phase shifter in FIG. 6. First, part of the first microstrip line M1 and part of the second microstrip lines M2 and M3 are formed. FIG. 7 is a diagram illustrating the first microstrip line M1 that is partially formed and uncompleted. FIG. 7 omits part of the phase shifter to illustrate the first microstrip line M1 in an enlarged manner. First body parts M1a and M1b including interrupted parts are formed as part of the first microstrip line M1. The first body part M1a is connected with the first source S1, and the first body part M1b is connected with the first drain D1. The first body part M1a and the first body part M1b are not connected with each other.

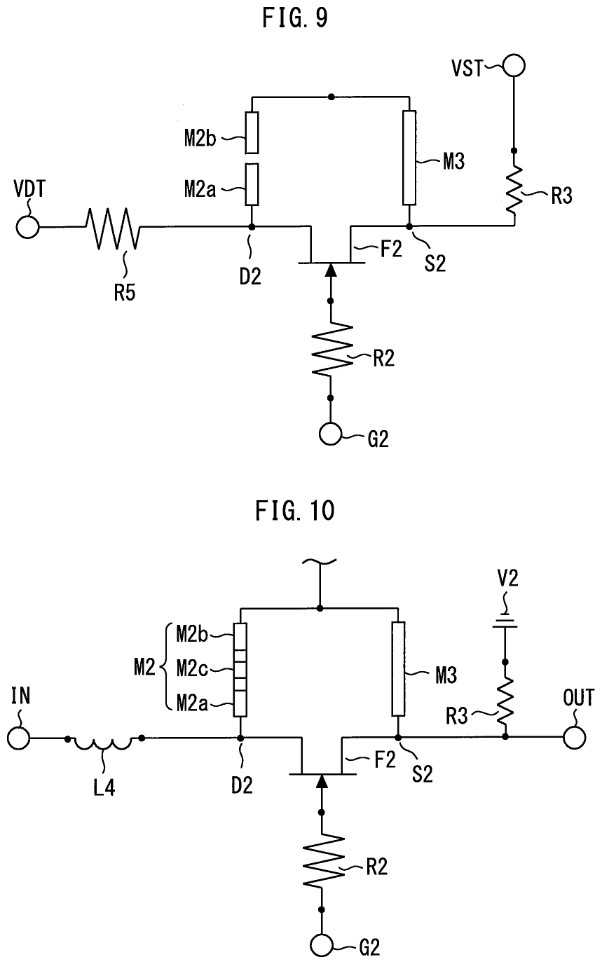

Part of the second microstrip lines M2 and M3 is formed simultaneously with, before, or after the formation of the first body parts M1a and M1b. FIG. 9 is a diagram illustrating the second microstrip lines M2 and M3 that are partially formed and uncompleted. Second body parts M2a and M2b including interrupted parts are formed as part of the second microstrip line M2, and the second microstrip line M3 is entirely formed. The second body part M2a is connected with the second drain D2, and the second microstrip line M3 is connected with the second source S2. However, the second body part M2a and the second body part M2b are separated from each other, and thus the interrupted parts are included in the second microstrip lines M2 and M3 as a whole.

At this stage, no microstrip line is connected between the first source S1 and the first drain D1 of the first transistor F1 as illustrated in FIG. 7, and no microstrip line is connected between the second source S2 and the second drain D2 of the second transistor F2 as illustrated in FIG. 9.

Then, the DC characteristics of the first transistor F1 and the second transistor F2 are inspected by using the inspection drain terminal VDT connected with the first drain D1 and the second drain D2, and the inspection source terminal VST connected with the first source S1 and the second source S2. Details of the inspection are as described above.

Then, the first microstrip line M1 and the second microstrip lines M2 and M3 are completed. FIG. 8 is a diagram illustrating the completed first microstrip line M1. As illustrated in FIG. 8, a first connection part M1c is formed at each interrupted part of the first body parts M1a and M1b, thereby forming the first microstrip line M1 including the first body parts M1a and M1b and the first connection part M1c. When the first connection part M1c is formed, the first source S1 and the first drain D1 are connected with each other through the first microstrip line M1. In other words, the first microstrip line M1 is connected in parallel with the first transistor F1.

FIG. 10 is a diagram illustrating the completed second microstrip lines M2 and M3. As illustrated in FIG. 10, second connection parts M2c are formed at interrupted parts of the second body parts M2a and M2b, thereby forming the second inductor L2 including the second body parts M2a and M2b and the second connection parts M2c. When the second connection parts M2c are formed, the second source S2 and the second drain D2 are connected with each other through the second microstrip lines M2 and M3. In other words, the second microstrip lines M2 and M3 are connected in parallel with the second transistor F2.

In a state in which each uncompleted microstrip line only including a body part is formed in this manner, the DC characteristics of the transistors are inspected, and connection parts of the microstrip lines are formed after the inspection, which completes the microstrip lines. For example, the first connection part M1c and the second connection part M2c may be formed by a plating method.

### Embodiment 3

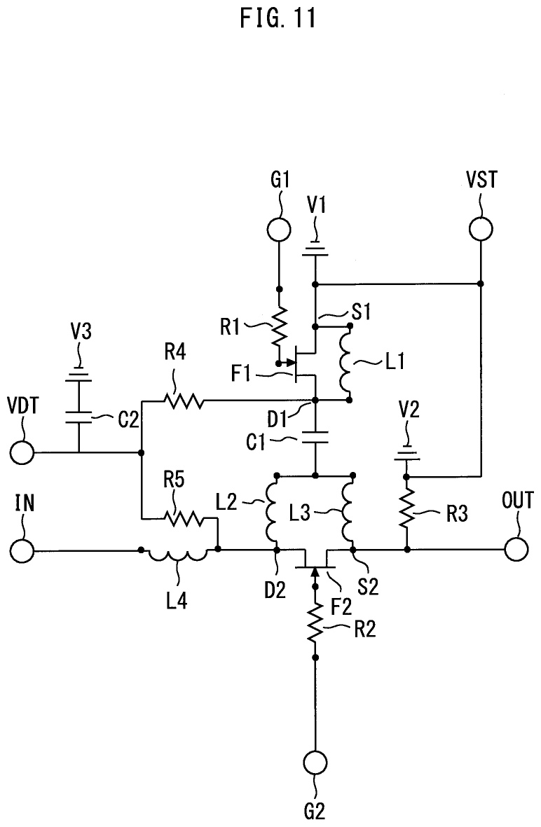

FIG. 11 is a circuit diagram of a phase shifter according to Embodiment 3. A capacitor C2 and a ground electrode V3 are connected between the inspection drain terminal VDT and each of the first resistor R4 and the second resistor R5. In other words, the capacitor C2 is provided to connect the ground electrode V3 and a wire connected with the inspection drain terminal VDT.

Coupling of high frequency signals occurs when the line connected with the inspection drain terminal VDT is positioned close to another circuit element or when a wire length L to the inspection drain terminal VDT satisfies L=λ(wavelength)/4*N(integral multiple). The coupling is reduced by the capacitor C2 and the ground electrode V3. Thus, influence of the wire length to the inspection drain terminal VDT on high frequency signals can be reduced. The capacitor C2 and the ground electrode V3 may be added to the circuit illustrated in FIG. 6.

The phase shifter described above in each embodiment may be a monolithic microwave integrated circuit (MMIC).

### REFERENCE SIGNS LIST

F1 first transistor; S1 first source; D1 first drain; F2 second transistor; S2 second source; D2 second drain; R4 first resistor; R5 second resistor; VDT inspection drain terminal; VST inspection source terminal

1. (canceled)

2. A phase shifter comprising:
a first transistor including a first source and a first drain;
a second transistor including a second source and a second drain;
a first inductor connected with the first source and the first drain, connected in parallel with the first transistor, and including a first body part having an interrupted part, and a first connection part formed at the interrupted part;
a second inductor connected with the second source and the second drain, connected in parallel with the second transistor, and including a second body part having an interrupted part, and a second connection part formed at the interrupted part;
an inspection drain terminal connected with the first drain and the second drain;
an inspection source terminal connected with the first source and the second source;
a first resistor connected in series with a wire connecting the first drain and the inspection drain terminal and having a resistance value of 2 kΩ or higher; and
a second resistor connected in series with a wire connecting the second drain and the inspection drain terminal and having a resistance value of 2 kΩ or higher.

3. The phase shifter according to claim 1 or 2, wherein the first inductor and the second inductor are spiral inductors.

4. (canceled)

5. A phase shifter comprising:
a first transistor including a first source and a first drain;
a second transistor including a second source and a second drain;
a first microstrip line connected with the first source and the first drain, connected in parallel with the first transistor, and including a first body part having an interrupted part, and a first connection part formed at the interrupted part;
a second microstrip line connected with the second source and the second drain, connected in parallel with the second transistor, and including a second body part having an interrupted part, and a second connection part formed at the interrupted part;
an inspection drain terminal connected with the first drain and the second drain;
an inspection source terminal connected with the first source and the second source;
a first resistor connected in series with a wire connecting the first drain and the inspection drain terminal and having a resistance value of 1.5 kΩ or higher; and
a second resistor connected in series with a wire connecting the second drain and the inspection drain terminal and having a resistance value of 1.5 kΩ or higher.

6. A phase shifter comprising:
a first transistor including a first source and a first drain;
a second transistor including a second source and a second drain;
a first inductor connected with the first source and the first drain, connected in parallel with the first transistor, and including a first body part having an interrupted part, and a first connection part formed at the interrupted part;
a second inductor connected with the second source and the second drain, connected in parallel with the second transistor, and including a second body part having an interrupted part, and a second connection part formed at the interrupted art;
an inspection drain terminal connected with the first drain and the second drain;
an inspection source terminal connected with the first source and the second source; and
a capacitor connecting a ground electrode and a wire connected with the inspection drain terminal.

7. The phase shifter according to claim 2, wherein the phase shifter is a monolithic microwave integrated circuit.

8.-10. (canceled)

11. The phase shifter according to claim 5, wherein the phase shifter is a monolithic microwave integrated circuit.

12. The phase shifter according to claim 6, wherein the phase shifter is a monolithic microwave integrated circuit.

13. A phase shifter comprising:
a first transistor including a first source and a first drain;
a second transistor including a second source and a second drain;
a first microstrip line connected with the first source and the first drain, connected in parallel with the first transistor, and including a first body part having an interrupted part, and a first connection part formed at the interrupted part;
a second microstrip line connected with the second source and the second drain, connected in parallel with the second transistor, and including a second body part having an interrupted part, and a second connection part formed at the interrupted part;
an inspection drain terminal connected with the first drain and the second drain;
an inspection source terminal connected with the first source and the second source; and
a capacitor connecting a ground electrode and a wire connected with the inspection drain terminal.

14. The phase shifter according to claim 13, wherein the phase shifter is a monolithic microwave integrated circuit.
